(19) United States
(12) Patent Application Publication
(10) Pub. No.: US 2007/0137574 A1
(43) Pub. Date: Jun. 21, 2007

(54) Low-cost and high performance solar cell manufacturing machine

(76) Inventors: Porponth Sichanugrist, Pathumthani (TH); Nirut Pingate, Pathumthani (TH); Jaran Sritharathikun, Pathumthani (TH); Peerawut Chinworarangsri, Pathumthani (TH); Patipan Krudtad, Pathumthani (TH); Somlak Khunraksa, Pathumthani (TH)

Correspondence Address: REED SMITH LLO, Suite 1400, 3110 Fairview Park Drive, Falls Church, VA, 22042, US

(21) Appl. No.: 11/642,900

(22) Filed: Dec. 21, 2006

(30) Foreign Application Priority Data
Dec. 21, 2005 (TH) 107273

(51) Int. Cl. C23C 16/00

(52) U.S. Cl. 118/723 E; 118/719; 118/728

(57) ABSTRACT

A solar cell manufacturing machine is configured to connect with a VHF frequency generator. The machine is used for coating an amorphous silicon film and a microcrystalline silicon film on a substrate vertically, and comprises a vacuum chamber, a box carrier positioned in the vacuum chamber, at least one hole shaped plate electrode vertically positioned in the box carrier, and a plurality of ground plates vertically positioned in the box carrier adjacent to the plate electrode. The plate electrode has defined thereon a plurality of holes formed to spread electromagnetic energy inputted into the plate electrode from the VHF frequency generator. The plate electrode and the plurality of ground plates are configured to form an electric field therebetween so as to coat at least one of an amorphous silicon film and a microcrystalline film on at least one substrate positioned between the plate electrode and the ground plates.

### FIELD OF THE INVENTION

The invention is directed to engineering technology involved with solar cells.

### BACKGROUND OF THE INVENTION

Solar energy is one of the appropriate alternative energy sources for Thailand due to the high intensity of sunlight shining on Thailand almost all year long. The type of solar cell, which is best used in Thailand, is amorphous silicon solar cell due to its reasonable price. Moreover, when the temperature is rising, the loss of its efficiency is the least comparing to single crystal solar cells and polycrystalline solar cells. At present, Thailand has two companies, which produce this kind of solar cell. Bangkok Solar Co., Ltd. has been manufacturing amorphous silicon solar cells since 2003 with its production technology called Single Chamber. Double layer of silicon solar cell structures, called Top cell and Bottom cell, respectively (a-Si/a-Si), are formed in this technology. The National Science and Technology Development Agency (NSTDA) by Energy Technology Center (ENTEC) can produce a solar cell with the highest performance of 15%. In addition, with cluster technology and double layers of silicon solar cell structure (a-Si/μc-Si), those agencies have achieved the development of a solar cell module with the performance of 8%.

Nowadays, there are two groups of technology for producing of amorphous silicon solar cells:

(1) Multi chamber production which is divided into;
a. Roll-to-roll technology
b. In-line technology
c. Cluster technology

(2) Single chamber production.

The two technologies have pros and cons as follows:

TABLE 1
Advantages And Disadvantages Of Technologies For Producing
Amorphous Silicon Solar Cell

| | Technology | Advantages | Disadvantages |
|---|---|---|---|
| 1 | Roll-to-roll | high production power | high cost machines |
| | | | hard to improve efficiency |
| | | | can be used with only roll substrate |
| | | | when running machine is out of |
| | | | order, many cells will be damaged |
| 2 | In-line | easy to improve efficiency | high cost machines |
| | | high production power | when the running machine is out of |
| | | not many cell will be damaged | order, production power will be |
| | | when the running machine is | decreased dramatically |
| | | out of order | |
| | | can be used with a wide variety | |
| | | of substrate | |
| 3 | Cluster | easy to improve efficiency | high cost machine |
| | | high production power | low production power |
| | | not many cell will be | |
| | | damaged when the | |
| | | running machine is out | |
| | | of order | |
| 4 | Single | low cost machines | hard to improve efficiency |
| | chamber | high production power | when running machine is out of |
| | | can be used with a wide variety | order, many cells will be damaged |
| | | of substrate | |

From information in the above table, it can be concluded that the most suitable technology to produce solar cell in Thailand is the Single Chamber type. Therefore, Bangkok Solar Co., Ltd. is using this simple technology due to its cheap substrate, which can be made in Thailand. Single Chamber technology (FIG. 1) has high production power because the substrate (No. 3, FIG. 1) can have many holes added in each single chamber. The electrode (No. 1, FIG. 1) will be fitted in between backing plates, which acts as ground (No. 2, FIG. 1). In addition, for one frequency generator, (No. 4, FIG. 1) 4 substrates can be coated with films (FIG. 1) at the same time. Currently, EPV Company in the USA and Bangkok Solar Co., Ltd. have adopted this technology to produce as many as 48 plate's substrates at the same time. By placing a flat plate electrode (FIG. 2) in between ground plates and a frequency generator of 13.56 MHz (Radio Frequency, RF), the substrate will be coated horizontally with film (FIG. 3) as it is placing on wheels (No. 1, FIG. 3). There are many wheels along the length of substrate in order to support and prevent it from falling. On the top, there are supporters to help sticking electrodes with ground (No. 2, FIG. 3). The efficiency of the finished solar cell is 47 W per one module or 5%. In terms of the cost, it costs US $1.79 per watt. However, it is found that the uniformity of films is not completely perfect because the film at the edge of the substrate is slightly thinner than in the middle (A. E. Delahoy et al., “Massive Parallel Processing For Low Cost a-Si Production”). Besides, to place the substrate horizontally on wheels, the areas on the wheels (No. 1, FIG. 4) as well as under the upper supporters (No. 2, FIG. 4) will not be coated with film. As a result of losing some areas for solar cells, the efficiency of the solar cell is reduced accordingly. Therefore, there should be a method to minimize the areas of lost solar cells.

In Single Chamber technology, a flat electrode is usually used with RF of 13.56 MHz. It is found that the use of this frequency causes problem in film coating for crystalline silicon because H₂ can ionize just a few of free radicals (H₂ free radicals, H⁺). These H₂ free radicals play an important role in film formation of microcrystalline silicon, which can enhance the efficiency of solar cells. Besides, to increase deposition rate by adding more energy is not a good solution because the increasing energy will affect the quality of the film as it creates defects in the film. The increase of film formation time is also impractical for commercial production.

Thus, to use a frequency higher than 13.56 MHz is one solution to create micro crystalline silicon films or to increase deposition rate. Generally, the frequency use ranges from 30 MHz-100 MHz, which are defined in Very High Frequency (VHF). In this very high frequency, SiH₄ and H₂ can be easily ionized without the use of high energy. As a result, the film will be well qualified and less defect. However, the use of VHF with the flat electrode, which is made of aluminum or stainless steel, will lead to inconsistencies in spreading electromagnetic waves over the electrode. When the frequency increases, the electrode's impedance increases accordingly; as a result the electromagnetic waves will be inconsistent. Thus, the uniformity of the film is not good or the thickness is not equal throughout the substrate. Moreover, the signal pole is attached to the middle edge of the bottom flat plate electrode and connected by a signal wire to the front of the chamber (FIG. 5). This resulted in the use of a long signal wire to connect with a VHF source. Because the use of a long signal wire has also increased its impedance, the energy transferring to the electrode has lost. It is necessary to design a new electrode to be compatible with VHF as well as help spread the signal equally throughout the plate. If the whole substrate is equally coated with film, the solar cell will be high-performance and cost-effective. Researchers have developed a new electrode to use with VHF in cluster technology. The new electrode can increase the deposition rate of microcrystalline silicon film formation. Solar cell modules from this electrode have increased efficiencies up to 8%. Thus, we have brought the new electrode to use in low-cost and high performance solar cell manufacturing machines.

### SUMMARY AND FEATURES OF THE INVENTION

This invention is a low-cost and high performance solar cell manufacturing machine. It at least consists of a vacuum chamber, an electrode, and a box carrier.

The electrode of the invention is directed to solving the problem that occurs when a flat plate electrode is used with VHF (30 MHz-100 MHz). The new electrode differs from the old flat plate electrode in that it is a flat plate with many holes (FIG. 6). The diameter of the holes is equal (No. 1, FIG. 6) and the distance between the holes is also equal (No. 2, FIG. 6). The signal pole is fixed in the middle of the front edge of the plate (No. 3 FIG. 6). This will shorten the length of the signal wire, which connects to the VHF generator (No. 4, FIG. 6). As a result, the loss of energy to the electrode will be reduced and also the working efficiency of the electrode is improved.

The impedance of a hole-shaped electrode will be changed accordingly with the required frequency. As a result, the electromagnetic wave will be spreading thoroughly all over the electrode. Therefore, the electric field between the electrode and the ground will be equal throughout the plate. Consequently, the film has also got good uniformity. The comparison of energy in the same-sized area shows that the hole-shaped electrode gets more energy than the ordinary flat plate electrode. Thus, the hole-shaped electrode consumes less energy than the normal flat plate electrode.

The box carrier was designed to solve the problem of losing solar cell area. It is different from the old box carrier because the substrate is vertically coated with film (FIG. 7). A comparison of the substrate that has been coated horizontally with the prior box carrier finds that the substrate of the invention has smaller areas that are not coated with film. Those areas include the areas on the wheels (No. 1, FIG. 8) and under the upper supporters (No. 2, FIG. 8). Consequently, the loss of solar cell areas in the invention is less than in the old box carrier. The new box carrier is an aluminum chamber. Inside, there are many parallel flat plate electrodes standing vertically. The flat plate electrodes are placed in between flat metal plates that are connected to the walls of the chamber and act as a ground for the system. The substrates are then attached to the electrodes and grounds in the chamber.

### BRIEF DESCRIPTION OF THE DRAWINGS

The present invention will be described herein below in conjunction with the accompanying drawings illustrating the invention, wherein:

FIG. 1 illustrates a solar cell manufacturing machine with flat plate electrode which is working with radio frequency (RF 13.56 MHz);

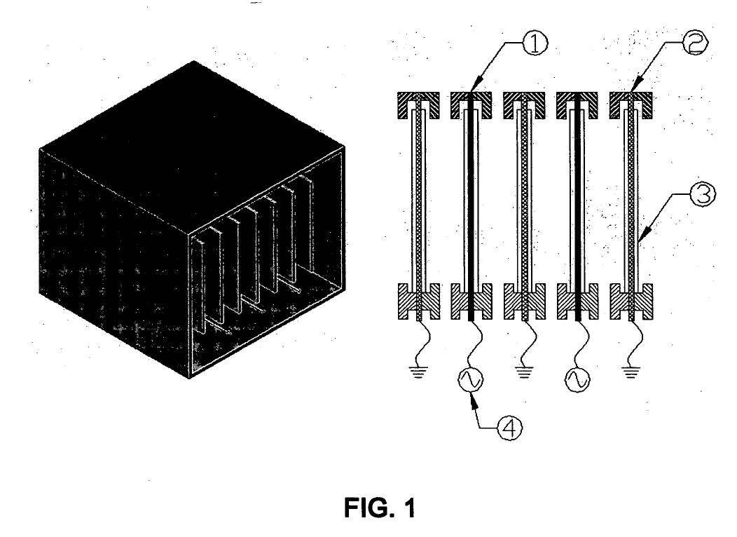

FIG. 2 illustrates a flat plate electrode;

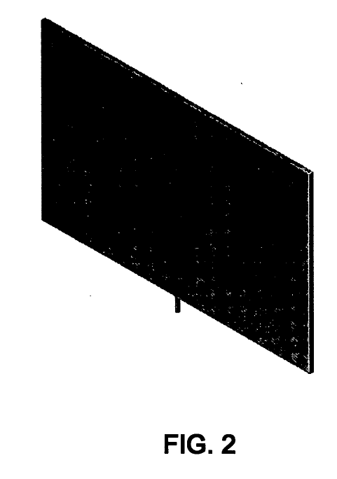

FIG. 3 illustrates a solar cell manufacturing machine that coated films horizontally;

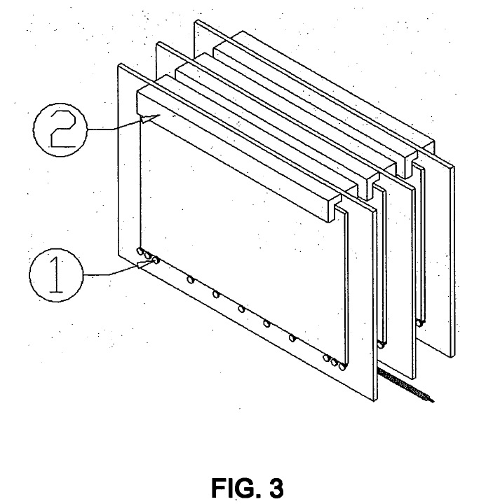

FIG. 4 illustrates the film which is coated horizontally;

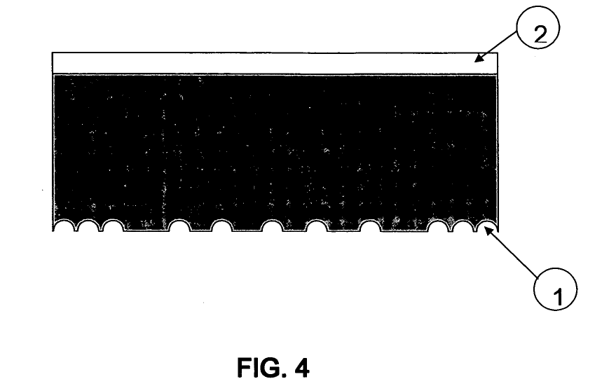

FIG. 5 illustrates the signal pole is attached at the middle edge of the bottom flat plate electrode and connected to VHF generator;

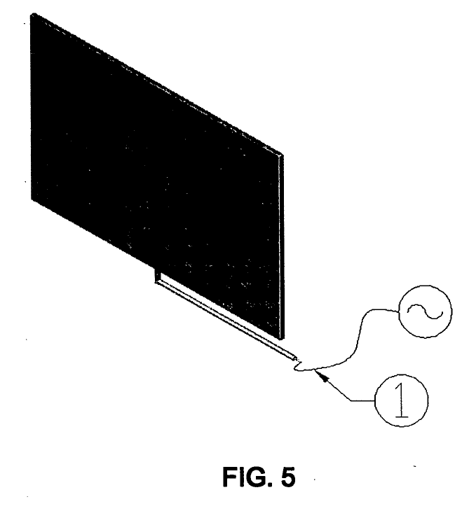

FIG. 6 illustrates a hole-shaped electrode and its signal pole which is fixed in the middle of the front edge of the electrode;

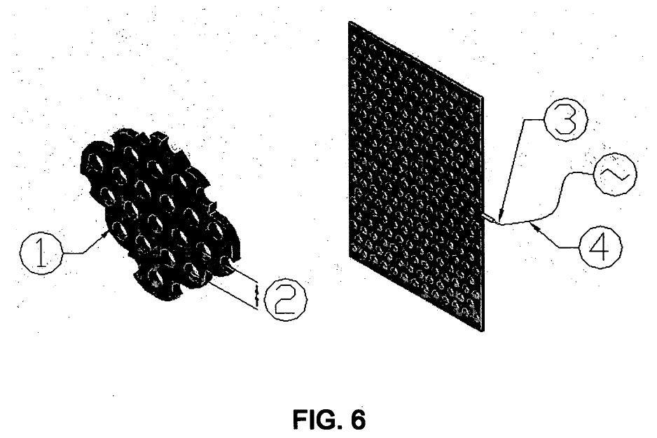

FIG. 7 illustrates a solar cell manufacturing machine with substrate which is coated film vertically;

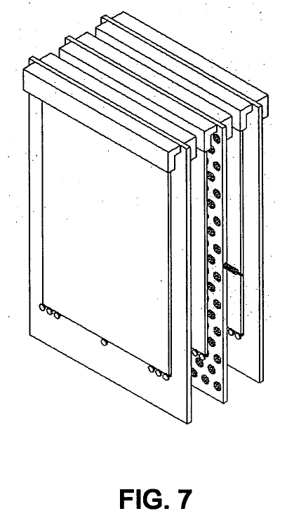

FIG. 8 illustrates a film from substrate which is coated vertically; and

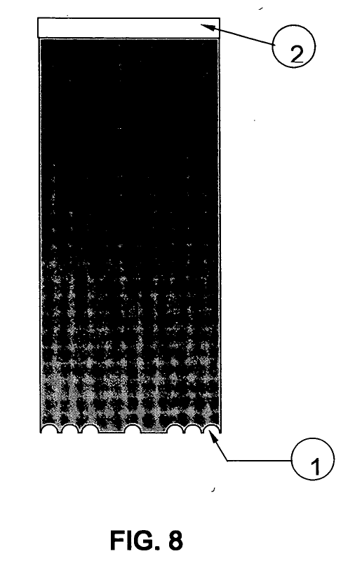

FIG. 9 illustrates a solar cell manufacturing machine with hole-shaped electrode working with VHF (30 MHz-100 MHz).

### DETAILED DESCRIPTION OF THE INVENTION

The low-cost and high performance solar cell manufacturing machine of the invention consists of the following components:

Vacuum Chamber

The chamber's body is made of stainless steel 304, welded in a box shape. Its dimensions are 1,700 mm×1,200 mm×1,000 mm. This chamber is connected to the vacuum pump to maintain its pressure to 1×10⁻⁶ Torr. There are 2 openings for taking the box carrier in and out. Outside, there are 4 heaters in each side for heating the substrate. At one side, there is an opening for a connection with a vacuum pump.

Electrode

It is a new designed electrode, which is called hole-shaped electrode. It is compatible with a VHF generator. It is made of flat aluminum with many holes through it. These holes have the same diameter and the same distance between them. After drilling holes, it needs to be rubbed with sandpaper to get rid of metal scraps. This also helps the substrate to attach tightly with the electrode.

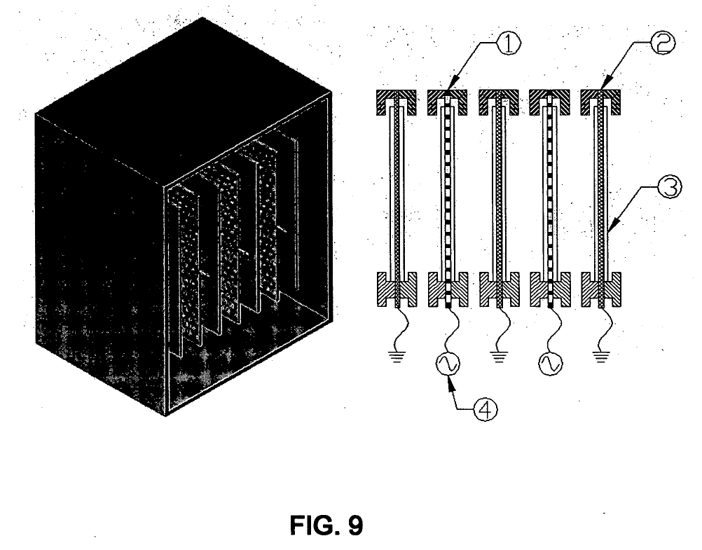

The high-performance solar cell manufacturing machine (FIG. 9) needs to work with VHF. Signal poles also need to be fixed in the middle of the front edge of the electrode in order to facilitate the connection with the VHF generator and reduce the length of the signal wire. As a result, the use of short signal wire will reduce the loss of energy transferring to the electrode. The hole-shaped electrode (No. 1, FIG. 9) will be placed in between flat plates (No. 2, FIG. 9) which are acted as a ground. One VHF generator (No. 4, FIG. 9) can coat film for 4 substrates at the same time (No. 3, FIG. 9)

Box Carrier

Box carrier was designed to be a rectangular box, which can place many electrodes and grounds vertically. Therefore, substrates will be vertically coated with film. The box carrier was made of aluminum with the dimensions of 1,480 mm×903 mm×813 mm. The front of it is open for putting substrates in and out. Gas box is connected in the rear of box carrier. It is a stainless steel box with small holes for spreading gas to box carrier. It is also used for mixing gases use in film coating. The openings on the top and bottom of box carrier can be opened and closed for letting the air flow in and out. They will be opened only when the substrate is heated. Inside the box carrier, there are many parallel hole-shaped electrodes standing vertically. Those electrodes are standing in between the same sized flat plates. Those flat plates are connected to the walls of the box and acted as a ground of the system. Substrates will be placed to touch every electrodes and grounds in the box. In the bottom of electrodes and grounds, there are small wheels to support and help inserting the substrate.

The hole-shaped electrode should be made of aluminum. The diameter of all holes should be equal. And the distance between the holes should be equal in order to define the impedance easily. After drilling the holes, it should be rubbed with sandpaper to get rid of metal scraps of the drilling. The electrode should be straight so that the substrate, which will be filmed, attaches tightly to it. Besides, the signal pole should be welded firmly to the front edge of the electrode so that the signal will be transferred efficiently. Every electrode and ground in the box carrier should be installed in the equal distance so that the thickness of film forming will be also equal. Small wheels are used for supporting and preventing the substrate from falling. They should be strong enough to support the substrate firmly and can be moved freely so that the substrate can be inserted easily. Before the real installation, all equipment should be cleaned with alcohol to get rid of dirt and grease.

Gas box should be connected to the rear of box carrier. The diameter of the hole should be equal so that the outlet gas will be equal. Consequently, the film uniformity will be good. Before the installation, all equipment should be cleaned to prevent the hole from clogging by dirt or metal scraps.

Although the present invention has been fully described in connection with the preferred embodiment thereof with reference to the accompanying drawings, it is to be noted that various changes and modifications will be apparent to those skilled in the art. Such changes and modifications are to be understood as included within the scope of the present invention as defined by the appended claims, unless they depart therefrom.

What is claimed is:

1. A solar cell manufacturing machine configured to connect with a VHF frequency generator, said machine being used for coating an amorphous silicon film and a microcrystalline silicon film on a substrate vertically, said machine comprising a vacuum chamber, a box carrier positioned in the vacuum chamber, at least one hole shaped plate electrode vertically positioned in the box carrier, and a plurality of ground plates vertically positioned in the box carrier adjacent to said plate electrode, wherein
said plate electrode has defined thereon a plurality of holes formed to spread electromagnetic energy inputted into said plate electrode from the VHF frequency generator, and
said plate electrode and said plurality of ground plates are configured to form an electric field therebetween so as to coat at least one of an amorphous silicon film and a microcrystalline film on at least one substrate positioned between said plate electrode and said ground plates.

2. A solar cell manufacturing machine according to claim 1, wherein said plate electrode includes a signal pole operatively positioned on a middle front edge portion thereof.

3. A solar cell manufacturing machine according to claim 1, wherein said plate electrode is made of aluminum.

4. A solar cell manufacturing machine according to claim 1, wherein each of said plurality of holes defined on said plate electrode has a diameter equal to one another, and each of said plurality holes are equidistant to one another.

5. A solar cell manufacturing machine according to claim 1, further comprising a plurality of hole shaped plate electrodes vertically positioned in the box carrier, wherein said plurality of ground plates are vertically positioned in the box carrier at least one of adjacent and between corresponding ones of said plurality of plate electrodes,
each of said plate electrodes has defined thereon a plurality of holes formed to spread electromagnetic energy inputted into said plate electrodes from the VHF frequency generator, and
each of said plurality of plate electrodes and corresponding ones of said plurality of ground plates are configured to form an electric field therebetween so as to coat at least one of an amorphous silicon film and a microcrystalline film on at least one substrate positioned between said plate electrodes and said ground plates.

6. A solar cell manufacturing machine according to claim 5, wherein each of said plurality of plate electrodes includes a signal pole operatively positioned on a middle front edge portion thereof.

7. A solar cell manufacturing machine according to claim 5, wherein each of said plurality of plate electrodes is made of aluminum.

8. A solar cell manufacturing machine according to claim 5, wherein each of said plurality of holes defined thereon have a diameter equal to one another, and each of said plurality holes are equidistant to one another.

9. A box carrier for solar cell manufacturing, said box carrier being configured to be positioned in a vacuum chamber and to connect with a VHF frequency generator, said box carrier comprising a rectangular chamber, a hole shaped plate electrode vertically positioned in the rectangular chamber, and a plurality of ground plates vertically positioned in the rectangular chamber adjacent to said plate electrode, wherein
said plate electrode has defined thereon a plurality of holes formed to spread electromagnetic energy inputted into said plate electrodes from the VHF frequency generator, and
said plate electrode and said plurality of ground plates are configured to form an electric field therebetween so as to coat at least one of an amorphous silicon film and a microcrystalline film on at least one substrate positioned between said plate electrode and said ground plates.

10. A box carrier for solar cell manufacturing according to claim 9, wherein said plate electrode includes a signal pole operatively positioned on a middle front edge portion thereof.

11. A box carrier for solar cell manufacturing according to claim 9, wherein said plate electrode is made of aluminum.

12. A box carrier for solar cell manufacturing according to claim 9, wherein each of said plurality of holes defined on said plate electrode has a diameter equal to one another, and each of said plurality holes are equidistant to one another.

13. A box carrier for solar cell manufacturing according to claim 9, further comprising a plurality of hole shaped plate electrodes vertically positioned in the rectangular chamber, wherein said plurality of ground plates are vertically positioned in the rectangular chamber at least one of adjacent and between corresponding ones of said plurality of plate electrodes,
each of said plate electrodes has defined thereon a plurality of holes formed to spread electromagnetic energy inputted into said plate electrodes from the VHF frequency generator, and
each of said plurality of plate electrodes and corresponding ones of said plurality of ground plates are configured to form an electric field therebetween so as to coat at least one of an amorphous silicon film and a microcrystalline film on at least one substrate positioned between said plate electrodes and said ground plates.

14. A box carrier for solar cell manufacturing according to claim 13, wherein each of said plurality of plate electrodes includes a signal pole operatively positioned on a middle front edge portion thereof.

15. A box carrier for solar cell manufacturing according to claim 13, wherein each of said plurality of plate electrodes is made of aluminum.

16. A box carrier for solar cell manufacturing according to claim 13, wherein each of said plurality of holes defined thereon have a diameter equal to one another, and each of said plurality holes are equidistant to one another.
